(19) United States
(12) Patent Application Publication
(10) Pub. No.: US 2026/0052894 A1
(43) Pub. Date: Feb. 19, 2026

(54) PEROVSKITE FILM FORMING METHOD AND PEROVSKITE FILM FORMING DEVICE

(71) Applicant: TORAY ENGINEERING CO., LTD., Tokyo (JP)

(72) Inventors: Takayuki MIYOSHI, Uji-city, Kyoto (JP); Toshifumi ITO, Moriyama-city, Shiga (JP); Toshiaki IKADA, Otsu-city, Shiga (JP)

(21) Appl. No.: 18/996,146

(22) PCT Filed: Jul. 6, 2023
(86) PCT No.: PCT/JP2023/025089

§ 371 Date: Jan. 17, 2025

(30) Foreign Application Priority Data
Jul. 21, 2022 (JP) 2022-116031

(51) Int. Cl. H10K 71/12; H10K 30/40

(52) U.S. Cl. CPC H10K 71/12; H10K 30/40

(57) ABSTRACT

A perovskite film forming method comprises: forming a perovskite film on a substrate; confirming a crystalline state of the perovskite film on the substrate by means of measurement; and adjusting operating condition in the forming of the perovskite film for a subsequent substrate on the basis of measurement result obtained in the confirming of the crystalline state. In the confirming of the crystalline state, a plurality of measurement positions are provided over the entire perovskite film on the substrate and numerical data are acquired for each measurement position to acquire a numerical data distribution of the crystalline state for the entire perovskite film.

### CROSS-REFERENCE TO RELATED APPLICATIONS

This application is a U.S. National stage of International Application No. PCT/JP2023/025089 filed on Jul. 6, 2023. This application claims priority to Japanese Patent Application No. 2022-116031 filed on Jul. 21, 2022 with Japan Patent Office. The entire disclosures of Japanese Patent Application No. 2022-116031 is hereby incorporated herein by reference.

### BACKGROUND

### Field of the Invention

The present invention relates to a perovskite film forming method and a perovskite film forming device for producing a perovskite solar cell.

### Background Information

As solar cells become more widespread in an effort to achieve a sustainable society, perovskite solar cells have attracted attention as a technology that could replace conventional silicon-based solar cells.

As disclosed in Japanese Laid-Open Patent Application Publication No. 2018-190928 (Patent Literature 1), for example, a perovskite solar cell is a solar cell that uses a perovskite semiconductor using perovskite, which has a crystal structure that converts solar light energy to electricity, and can achieve a similar conversion efficiency as conventional silicon-based solar cells while being thin and thus is adaptable to flexible configurations. There also are advantages, such as not requiring rare metals, being able to be produced by coating, and being able to be formed inexpensively with a relatively low-temperature process.

### SUMMARY

On the other hand, perovskite has poor stability during crystal growth, so the crystalline state could change greatly due to slight differences in the perovskite film forming conditions, such as coating and drying. Since the crystalline state of the perovskite film is directly connected to the power generation performance of the perovskite solar cell, there is the problem that if the desired crystalline state cannot be obtained over the entire perovskite film, the perovskite solar cell cannot exhibit the desired power generation performance.

One object of the present disclosure is to provide a perovskite film forming method and a perovskite film forming device with which it is possible to obtain a perovskite solar cell that has stable power generation efficiency.

In order to solve the problem described above, a perovskite film forming method of the present disclosure comprises a film-forming step for forming a perovskite film on a substrate, a crystalline state confirmation step for confirming the crystalline state of the perovskite film on the substrate by means of measurement, and a condition adjustment step for adjusting operating conditions in the film-forming step for subsequent substrates on the basis of the measurement result obtained in the crystalline state confirmation step, wherein, in the crystalline state confirmation step, a plurality of measurement positions are provided over the entire perovskite film on the substrate, and numerical data are acquired for each measurement position to acquire a numerical data distribution of the crystalline state for the entire perovskite film.

In the perovskite film forming method of the present disclosure, the crystalline state of the entire perovskite film can be ascertained by acquiring the numerical data distribution of the crystalline state in the crystalline state confirmation step, and the conditions for the film-forming step can be immediately reviewed in the condition adjustment step so that the crystalline state is improved overall for the subsequent substrates.

In addition, in the condition adjustment step, the operating conditions of the film-forming step are preferably adjusted so that the numerical data distribution acquired in the subsequent crystalline state confirmation steps falls within a prescribed numerical range over the entire perovskite film.

It is thereby possible to easily obtain a perovskite solar cell with a stable power generation efficiency.

In addition, it is preferable to accumulate numerical data distributions from past crystalline state confirmation steps together with information on the operating conditions of the film-forming steps, forming a data group, and to adjust the operating conditions in the film-forming step for the subsequent substrates by also using the data group information.

In this manner, it is possible to efficiently carry out the condition adjustment step.

Additionally, in the crystalline state confirmation step, it is preferable to acquire the absorption spectrum of light irradiated on the perovskite film, and to acquire the wavelength at the long-wavelength side edge of the absorption spectrum as the numerical data.

In this manner, it is possible to acquire parameters directly linked to the power generation efficiency of the perovskite solar cell at each measurement position and to carry out the condition adjustment step on the basis of these parameters.

Additionally, in the crystalline state confirmation step, it is preferable to acquire the absorption spectrum of light irradiated on the perovskite film, and to acquire the light absorbance at the short-wavelength region of the absorption spectrum as the numerical data.

In this manner, it is possible to evaluate the density of the crystals.

Additionally, in the crystalline state confirmation step, it is preferable to acquire the surface roughness of the perovskite film as the numerical data.

In this manner, it is possible to ascertain the crystalline state by estimating the size of the crystals of the perovskite film at each measurement position, and to carry out the condition adjustment step on the basis thereof.

In addition, in the crystalline state confirmation step, it is preferable to implement a photoluminescence method to acquire, as the numerical data, the peak wavelength of light emitted from the perovskite film.

In this manner, it is possible to easily ascertain the power generation efficiency of the perovskite film for each measurement position, and to carry out the condition adjustment step on the basis thereof.

In addition, the film-forming step preferably includes a coating step for forming a coating film containing perovskite on a substrate by coating, and a drying step for drying the coating film formed on the substrate to form the perovskite film, wherein, in the condition adjustment step, the forming conditions of the coating film in the coating step and/or the drying conditions of the coating film in the drying step are preferably adjusted.

In addition, the crystalline state confirmation step and the condition adjustment step are preferably executed each time the film-forming step is executed.

In this manner, when forming a perovskite film, which has unstable crystal formation, information on the crystalline state of the perovskite film on the previous substrate can be swiftly fed back to the formation of the perovskite film on the subsequent substrates, making it possible to obtain a perovskite solar cell that has stable power generation efficiency in many substrates.

In addition, in order to solve the problem described above, a perovskite film forming method of the present disclosure comprises: a film-forming step including a coating step for forming a coating film containing perovskite on a substrate by coating, and a drying step for drying the coating film formed on the substrate to form the perovskite film; a crystalline state confirmation step for confirming the crystalline state of the coating film on the substrate by means of measurement; and a condition adjustment step for adjusting operating conditions in the film-forming step on the basis of the measurement result obtained in the crystalline state confirmation step, in which, in the crystalline state confirmation step, a plurality of measurement positions are provided over the entire coating film on the substrate and numerical data are acquired for each measurement position to acquire a numerical data distribution of the crystalline state for the entire coating film, wherein the drying step includes a first drying step for increasing crystal nuclei of perovskite and a second drying step for growing perovskite crystals around the crystal nuclei after the first drying step, and the crystalline state confirmation step is carried out during the first drying step or after the first drying step and before the second drying step.

In the perovskite film forming method of the present disclosure, the crystalline state of the entire coating film can be ascertained by acquiring the numerical data distribution of the crystalline state in the crystalline state confirmation step, and the conditions for the film-forming step can be immediately reviewed in the condition adjustment step so that the crystalline state is improved overall for the subsequent substrates. In addition, by carrying out the crystalline state confirmation step before the formation of the perovskite film in the second drying step, the drying conditions can be evaluated separately from the second drying step, especially when the first drying step greatly affects the crystalline state of the perovskite film.

In addition, the first drying step may be a reduced-pressure drying step in which the coating film is maintained under a reduced-pressure environment.

Since small differences in the drying time greatly affects the crystal density of the perovskite film in a reduced-pressure drying step, it is particularly effective to carry out the crystalline state confirmation step before the second drying step.

In addition, the crystalline state confirmation step is preferably carried out after a prescribed period of time has elapsed after the start of the first drying step.

In this manner, by keeping the timing consistent at which the crystalline state is confirmed in the formation of perovskite film over a plurality of times, it becomes possible to accurately evaluate effects of the drying conditions on the crystalline state of the perovskite film.

In addition, in the crystalline state confirmation step, it is preferable to carry out measurements at the plurality of measurement positions essentially simultaneously.

As a result, it becomes possible to keep the timing consistent at which the crystalline state is confirmed for each measurement position, and to accurately evaluate the effects of the drying conditions on the crystalline state of the perovskite film.

Additionally, in order to solve the problem described above, a perovskite film forming device of the present disclosure comprises a film-forming unit for forming a perovskite film on a substrate, and a crystalline state confirmation unit for confirming the crystalline state of the perovskite film on the substrate by means of measurement, wherein, in the crystalline state confirmation unit, a plurality of measurement positions are provided over the entire perovskite film on the substrate and numerical data are acquired for each measurement position to acquire a numerical data distribution of the crystalline state for the entire perovskite film.

In the perovskite film forming device of the present disclosure, the crystalline state of the entire perovskite film can be ascertained by acquiring the numerical data distribution of the crystalline state with the crystalline state confirmation unit, and the operating conditions for the film-forming unit can be immediately reviewed so that the crystalline state is improved overall for the subsequent substrates.

In addition, in order to solve the problem described above, a perovskite film forming device of the present disclosure comprises a film-forming unit including a coating unit for forming a coating film containing perovskite on a substrate by coating, and a drying unit for drying the coating film formed on the substrate to form the perovskite film, and a crystalline state confirmation unit for confirming the crystalline state of the coating film on the substrate by means of measurement, in which, in the crystalline state confirmation unit, a plurality of measurement positions are provided over the entire coating film on the substrate and numerical data are acquired for each measurement position to acquire a numerical data distribution of the crystalline state for the entire coating film, wherein the drying unit includes a first drying unit for increasing crystal nuclei of perovskite and a second drying unit for growing perovskite crystals around the crystal nuclei after a first drying step carried out by the first drying unit, and the crystalline state confirmation unit confirms the crystalline state of the coating film during the drying step carried out by the first drying unit or after the first drying step and before a second drying step carried out by the second drying unit.

In the perovskite film forming device of the present disclosure, the crystalline state of the entire coating film can be ascertained by acquiring the numerical data distribution of the crystalline state with the crystalline state confirmation unit, and the operating conditions of the film-forming unit can be immediately reviewed so that the crystalline state is improved overall for the subsequent substrates. In addition, by confirming the crystalline state before the formation of the perovskite film by means of the second drying, the drying conditions can be evaluated separately from the heating and drying step, especially when the first drying step greatly affects the crystalline state of the perovskite film.

In addition, the first drying unit may be a reduced-pressure drying unit that maintains the coating film under a reduced-pressure environment.

Since small differences in the drying time greatly affects the crystal density of the perovskite film in a reduced-pressure drying step, it is particularly effective to carry out the crystalline state confirmation step before the second drying step.

In addition, the crystalline state confirmation unit preferably has a plurality of measuring means, and each of the measuring means preferably carries out measurements at each of the measurement positions.

As a result, it becomes possible to keep the timing consistent at which the crystalline state is confirmed for each measurement position, and to accurately evaluate the effects of the drying conditions on the crystalline state of the perovskite film.

By using the perovskite film forming method and the perovskite film forming device of the present disclosure, it is possible to obtain a perovskite solar cell that has stable power generation efficiency.

### BRIEF DESCRIPTION OF THE DRAWINGS

FIG. 1 is a diagram explaining a perovskite film forming device according to one embodiment of the present disclosure.

FIG. 2 is a diagram explaining an example of a measurement result obtained in a crystalline state confirmation step in a perovskite film forming method according to the present embodiment.

FIG. 3 is a diagram explaining the crystalline state confirmation step in the perovskite film forming method according to the present embodiment.

FIG. 4 is a diagram explaining an example of a data group accumulated in a storage device.

FIG. 5 is a diagram explaining a crystalline state confirmation unit in a perovskite film forming device according to another embodiment of the present disclosure.

FIG. 6 is a diagram explaining a perovskite film forming device according to another embodiment of the present disclosure.

### DETAILED DESCRIPTION OF EMBODIMENTS

### Embodiment 1

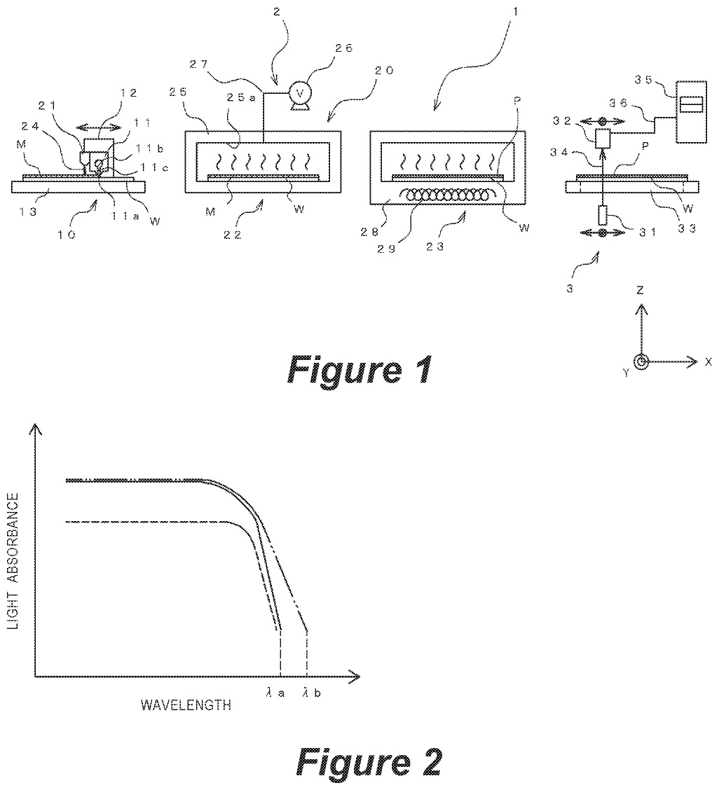

A perovskite film forming device for carrying out a perovskite film forming method according to one embodiment of the present disclosure will be described with reference to FIG. 1.

A perovskite film forming device 1 comprises a film-forming unit 2 and a crystalline state confirmation unit 3. The film-forming unit 2 forms, on a substrate W, a perovskite film P constituting a composition (perovskite) such as methylammonium lead iodide (MAPbI3) having a perovskite crystal structure, and the crystalline state confirmation unit 3 confirms the crystalline state of the perovskite film P formed on the substrate W by measurement. The result confirmed by the crystalline state confirmation unit 3 is reflected on the setting of the conditions for forming the perovskite film P on the subsequent substrates W by the film-forming unit 2, so that a perovskite film P with a better crystalline state is formed.

The substrate W is a part of a perovskite solar cell, in which a hole transport layer is stacked on a transparent electrode, in which a transparent conductive layer is formed on a support made of a material that transmits sunlight, such as quartz glass. The perovskite film P is formed thereon by the perovskite film forming device 1. Thereafter, an electron transport layer and a back electrode are further formed on the perovskite film P, thereby obtaining a perovskite solar cell.

In the present embodiment, the film-forming unit 2 includes a coating unit 10 for forming a coating film M containing perovskite on a substrate W by coating, and a drying unit 20 for drying the coating film M formed on the substrate W, and the film-forming unit 2 forms the perovskite film P by drying the coating film M on the substrate W.

The coating unit 10 has a slit nozzle 11, a gantry 12, and a stage 13. A coating liquid, which is a solution in which a perovskite material is dissolved in a solvent, is discharged toward the substrate W while the slit nozzle 11 moves relative to the substrate W, which is held by the stage 13, thereby forming a coating film M on the substrate W.

The stage 13 has a substrate holding surface, which is a horizontal surface for placing the substrate W thereon. Suction holes connected to an undiagrammed pressure reduction means are provided at a plurality of locations on this substrate holding surface, and by the pressure reduction means being operated in a state in which the substrate W is placed on the substrate holding surface, the stage 13 suctions and holds the substrate W. The substrate W is placed such that the surface of the substrate W on the side opposite to the surface on which the hole transport layer is stacked faces the substrate holding surface; therefore, the substrate W is suctioned and held such that the surface on which the hole transport layer is stacked faces upward.

The slit nozzle 11 has a discharge port 11a located above the stage 13 and extending in the horizontal direction, and discharges coating liquid from this discharge port 11a. In this description, the longitudinal direction (depth direction of the paper in FIG. 1) of the discharge port 11a is referred to as the Y-axis direction, the horizontal direction perpendicular to the Y-axis direction is referred to as the X-axis direction, and the vertical direction is referred to as the Z-axis direction.

A manifold 11b that is a space for temporarily holding coating liquid and that is elongated in the Y-axis direction similar to the discharge port 11a, and a slit 11c that connects the manifold 11b and the discharge port 11a, are formed inside the slit nozzle 11. The manifold 11b is connected, via a piping, to an undiagrammed tank that stores the coating liquid, and the coating liquid that is sent from the tank to the manifold 11b by the undiagrammed pump spreads in the Y-axis direction in the manifold 11b, passes through the slit 11c, and is discharged from the discharge port 11a. As a result, the coating liquid is discharged at an essentially uniform rate along the Y-axis direction.

This slit nozzle 11 is attached to the gate-shaped gantry 12 that straddles the stage 13 in the Y-axis direction. This gantry 12 has a linear motion mechanism extending in the X-axis direction, and the slit nozzle 11 moves in the X-axis direction by the operation of this linear motion mechanism. In a state in which the substrate W is held on the stage 13, the slit nozzle 11 moves over the substrate W in the X-axis direction while discharging the coating liquid from the discharge port 11a, thereby forming, on the substrate W, the coating film M expanding in the X and Y directions.

In addition, the length of the discharge port 11a in the Y-axis direction is approximately equal to the Y-axis-direction length of the substrate W held on the stage 13; therefore, with the operation of the slit nozzle 11 and the gantry 12, the coating film M is formed over almost the entire surface (surface on which the hole transport layer is stacked) of the substrate W facing the discharge port 11a.

In addition, the slit nozzle 11 is attached to the gantry 12 via an undiagrammed linear motion mechanism in the Z-axis direction, and the distance (gap) between the discharge port 11a and the substrate W is adjusted by the operation of this linear motion mechanism. Additionally, the movement speed of the slit nozzle 11 achieved by the gantry 12 can also be adjusted. By controlling the gap, the movement speed of the slit nozzle 11, the speed at which the coating liquid is delivered from the tank to the manifold 11b, and the like, the coating conditions of the coating liquid from the slit nozzle 11 to the substrate W are adjusted.

In the present embodiment, the drying unit 20 is composed of three drying means, an air knife 21 that blows dry air 24 onto the coating film M immediately after application onto the substrate W, a reduced-pressure drying unit 22 that causes the solvent in the coating film M to evaporate by reducing the pressure, and a heating and drying unit 23 that sinters the coating film M to ultimately obtain the perovskite film P. The substrate W on which the coating film M has been formed by the coating unit 10 is passed through the air knife 21, the reduced-pressure drying unit 22, and the heating and drying unit 23 in that order to dry the coating film M, and crystallization of the perovskite in the coating film M progresses as the solvent in the coating film M evaporates in each of the drying means.

The air knife 21 is a device that blows the dry air 24 downward and is attached to the gantry 12 together with the slit nozzle 11.

This air knife 21 is disposed so as to be near the slit nozzle 11 on the upstream side of the slit nozzle 11 in the movement direction of the slit nozzle 11 (X-axis direction). As a result of the slit nozzle 11, the air knife 21, and the gantry 12 being operated simultaneously, formation of the coating film M on the substrate W can be advanced while carrying out initial drying with the dry air 24 immediately after the coating liquid discharged from the slit nozzle 11 lands on the substrate W.

Here, in the coating film M containing perovskite, crystallization starts as the solvent evaporates immediately after being formed on the substrate W. An unevenness in the evaporation of the solvent at this time directly leads to an uneven crystalline state of the perovskite film P, so it is useful to control the behavior of the drying of the coating film M immediately after application with the air knife 21, as in the present embodiment. In addition, the gas blown from the air knife 21 is dry air 24 in the present embodiment, but the invention is not limited thereto; gases other than air, such as nitrogen or argon, may be employed.

In addition, the air knife 21 is attached to the gantry 12 via a linear motion mechanism in the Z-axis direction that is different from the linear motion mechanism in the Z-axis direction to which the slit nozzle 11 is attached, so the slit nozzle 11 and the air knife 21 can be moved independently in the Z-axis direction. As a result, the gap between the substrate W and the air knife 21 can be adjusted separately from the gap between the substrate W and the slit nozzle 11, and, by controlling the gap between the substrate W and the air knife 21, the volume and temperature of the dry air 24 blown out from the air knife 21, and the like, the drying conditions of the coating film M can be adjusted by the air knife 21.

The reduced-pressure drying unit 22 is a device for drying the coating film M on the substrate W under reduced pressure, the device comprising a reduced-pressure chamber 25 in which a reduced-pressure space 25a is formed, and a pressure reduction means 26, such as a vacuum pump, connected to the reduced-pressure space 25a from the outside of the reduced-pressure chamber 25 via a piping 27.

The reduced-pressure chamber 25 has an undiagrammed shutter; the substrate W is transported from the outside of the reduced-pressure chamber 25 to the reduced-pressure space 25a when this shutter is opened, and the reduced-pressure space 25a cut off from the outside air when the shutter is closed.

By the pressure reduction means 26 being operated when the shutter of the reduced-pressure chamber 25 is closed, the reduced-pressure space 25a is decompressed. Then, as a result of the reduced-pressure space 25a being decompressed when the substrate W is placed in the reduced-pressure space, the boiling point of the solvent in the coating film M on the substrate W decreases, causing the solvent to evaporate. That is, the coating film M is dried under reduced pressure in the reduced-pressure chamber 25.

In this reduced-pressure drying unit 22, the temperature of the reduced-pressure space 25a at the time of reduced-pressure drying, the decompression speed of the pressure reduction means 26, and the like, are controlled to adjust the drying conditions of the coating film M. In the present description, the reduced-pressure drying unit 22 is also referred to as the first drying unit, and the step for drying the coating film M with this reduced-pressure drying unit 22 is referred to as the first drying step. In this first drying step, the solvent of the coating film Mis caused to evaporate under a condition of lower than a prescribed temperature (for example, 130° C.), whereby a phenomenon in which perovskite crystal nuclei are formed (increased) in the coating film M primarily occurs, and the number of crystal nuclei formed in the coating film M increases as the drying time increases. For this reason, the first drying step is also referred to as the crystal nuclei formation step in the present description.

The heating and drying unit 23 is a device that sinters the coating film M that has been dried under reduced pressure by the reduced-pressure drying unit 22 to obtain the perovskite film P, and has a stage 28 on which the substrate W is placed and a heater 29 that heats the stage 28. By heating with this heater 29 to a temperature at which the coating film M can be sintered or higher, the solvent in the coating film M evaporates further and drying of the coating film M advances, and, ultimately, the coating film M is sintered and the perovskite film P is formed.

In this heating and drying unit 23, the temperature set in the heating and drying unit 23, the heating time of the substrate W, and the like, are controlled to adjust the drying conditions for the coating film M. In the present description, the heating and drying unit 23 is also referred to as the second drying unit, and the step for drying the coating film M with the heating and drying unit 23 is referred to as the second drying step. In this second drying step, when the perovskite crystals in the coating film M are heated to a prescribed temperature (for example, 130° C.) or more, a phenomenon in which the perovskite crystals grow around the crystal nuclei and become large occurs primarily. For this reason, the second drying step is also referred to as the crystal growth step in the present description. By adjusting the conditions of the crystal nuclei formation step and the crystal growth step, it is possible to adjust the size and density of the perovskite crystals forming the perovskite film P.

The perovskite film P is formed on the substrate W by the operation of the film-forming unit 2 (coating unit 10 and drying unit 20) described above. The step for forming the perovskite film P on the substrate W in this manner is referred to as the film-forming step in the present description. In addition, the step for forming the coating film M containing perovskite on the substrate W by means of coating during the film-forming step as in the present embodiment is referred to as the coating step, and the step for drying the coating film M formed on the substrate W to form the perovskite film P is referred to as the drying step.

In the present embodiment, the crystalline state confirmation unit 3 includes a light source 31, a spectral detector 32, and a stage 33. Light 34 is irradiated from the light source 31 onto the perovskite film P on the substrate W held by the stage 33, and the light 34 reflected by the perovskite film P is captured by the spectral detector 32 to carry out a measurement. The result data measured by the spectral detector 32 are transmitted to a storage device 35 via a cable 36.

The stage 33 has a substrate holding surface, which is a horizontal surface for placing the outer peripheral portion of the substrate W thereon, and the inner side of this substrate holding surface is hollow as viewed in the up-down direction. Suction holes connected to an undiagrammed pressure reduction means are provided at a plurality of locations on this substrate holding surface, and by the pressure reduction means being operated in a state in which the substrate W is placed on the substrate holding surface, the stage 33 suctions and holds the outer peripheral portion of the substrate W. The substrate W is placed such that the surface of the substrate W on the side opposite to the surface on which the perovskite film P is formed faces the substrate holding surface; therefore, the substrate W is suctioned and held such that the perovskite film P faces upward.

The light source 31 emits, from below, the light 34 containing light in a prescribed wavelength range toward the perovskite film P, and the light 34 emitted from the light source 31 passes through the hollow portion of the stage 33 and reaches the lower surface of the substrate W. Then, the light 34 is transmitted through the substrate W and reaches the perovskite film P.

The light 34 emitted from the light source 31 most preferably contains all of the light from the ultraviolet range to the near infrared range; however, in the present embodiment for confirming the crystalline state of the perovskite film P for solar cells, it is sufficient for the light to contain at least light with a wavelength of about 2=400 nm to 1000 nm (violet light to near infrared light).

In the present embodiment, the spectral detector 32 is a known spectroscope provided above the stage 33 which carries out spectroscopic measurement on the incident light to obtain a spectral distribution. In addition, in the present embodiment, this spectral detector 32 has at least the capability of measuring the above-mentioned light having a wavelength of about λ=400 nm to 1000 nm.

Here, in the present embodiment, the light source 31 and the spectral detector 32 are arranged to have a positional relationship such that the light 34 emitted from the light source 31 is transmitted through the substrate W and the perovskite film P and enters the spectral detector 32.

In addition, the light source 31 and the spectral detector 32 are each mounted on an undiagrammed moving means that can move in the X-axis and Y-axis directions; the light source 31 moves below the stage 33 and the spectral detector 32 moves above the stage 33 in conjunction with each other in the X and Y directions. As a result, the light source 31 and the spectral detector 32 move relative to the substrate W while maintaining the positional relationship in which the light 34 emitted from the light source 31 enters the spectral detector 32.

The storage device 35 is a hard disk, a memory unit such as RAM or ROM, or the like, provided in a computer, and stores measurement result data obtained by the spectral detector 32, which are transmitted thereto from the spectral detector 32 via the cable 36. In addition, in the present embodiment, the storage device 35 stores information on the operating conditions of the perovskite film P forming step for which the spectral detector 32 carried out a measurement, and a data group is formed from both the measurement result data and the operating conditions, as described further below.

In addition, the computer equipped with this storage device 35 may be used to control the operation of each component device of the film-forming unit 2 and the crystalline state confirmation unit 3.

The operation of confirming the crystalline state of the perovskite film P carried out by the crystalline state confirmation unit 3 in the present embodiment will be described next.

The perovskite film P is a so-called semiconductor, and has a band gap Eg as a parameter. When the photon energy hv (=hc/λ=1239.8/λ) (h is Planck's constant, c is the speed of light, and v is the frequency of light) of the light that enters the perovskite film P is greater than the band gap Eg, the light is absorbed and electrons move within the perovskite film P. That is, electricity is generated.

On the other hand, when the photon energy hv is smaller than the band gap Eg, the light is not absorbed. Accordingly, when the light made incident on the perovskite film P contains light in a prescribed wavelength range, and a wavelength λ that satisfies the following equation (1) is included in said wavelength range, light with a wavelength shorter than λ is absorbed by the perovskite film P, and light with a wavelength longer than λ is not absorbed by the perovskite film P.

$$Eg = 1239.8 / λ \qquad ( 1 )$$

In order to utilize the characteristics described above, in the present embodiment, the light 34 is emitted from the light source 31, which is reflected by the perovskite film P and then made incident on the spectral detector 32, to measure the absorption spectrum. FIG. 2 shows an example of what a result of measuring the absorption spectrum with the spectral detector 32 at this time may look like.

For example, in the case that the measurement results of the absorption spectrum at a given position on the perovskite film P form a curve as indicated by the solid line in FIG. 2, wavelength λa corresponding to the edge (break) of the curve on the long-wavelength side is the wavelength that satisfies the above-described equation (1); the edge of the absorption spectrum, such as this wavelength λa, is referred to as the absorption edge in this description.

Here, the band gap Eg of the perovskite film P changes in accordance with the crystalline state (particularly the crystal size) of the perovskite film P. In that case, the wavelength of the absorption edge also changes according to equation (1). Therefore, if the crystalline state is not uniform within the perovskite film P, even if the wavelength of the absorption edge is the wavelength λa at a certain location, as shown by the solid line in FIG. 2, at another location, the wavelength of the absorption edge becomes wavelength Ab that is different from wavelength λa, as shown by the dotted line in FIG. 2.

In addition, the band gap Eg is a value correlated with the power generation efficiency of the solar cell, so if the band gap Eg is not uniform within the perovskite film P, even if the result of measuring the band gap Eg at one portion is good, there is the possibility that a good power generation efficiency cannot be obtained from the perovskite film P as a whole, which is not preferable.

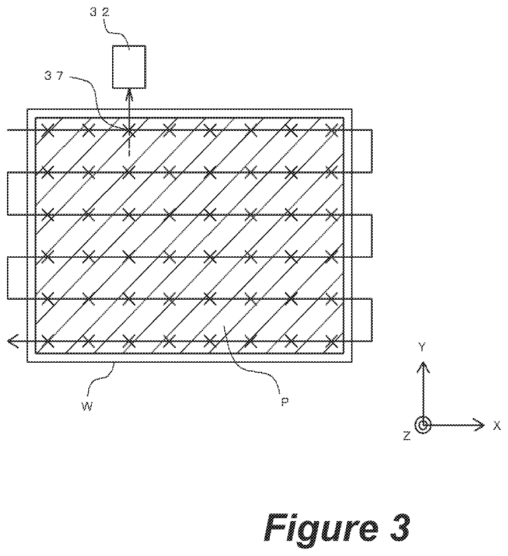

Therefore, in the present embodiment, the crystalline state confirmation unit 3 confirms, by means of measurement, whether the wavelength of the absorption edge is essentially uniform over the entire perovskite film P as an index of determining whether the crystalline state is essentially uniform over the entire perovskite film P. Specifically, the crystalline state confirmation unit 3 measures the absorption spectrum at a plurality of points on the perovskite film P while moving the light source 31 and the spectral detector 32 in the X and Y directions to measure the wavelength of the absorption edge at each of a plurality of measurement positions 37 over the entire perovskite film P, as shown in FIG. 3. The wavelengths (numerical data) of a plurality of absorption edges obtained in this manner are compiled and acquired as the numerical data distribution of the crystalline state of the perovskite film P. The numerical data distribution obtained in this manner is stored in the storage device 35 together with each piece of parameter information used in the film-forming step when forming the perovskite film P.

The step in which the crystalline state of the perovskite film P is confirmed by operating the crystalline state confirmation unit 3 described above is referred to as the crystalline state confirmation step in the present disclosure.

Here, particularly when forming the perovskite film P having an unstable crystal formation process, unevenness in the crystalline state may occur even if the perovskite film P is formed by carrying out the coating step and the drying step under uniform conditions over the entire surface. Therefore, in order to know whether the power generation efficiency of the perovskite solar cell using the perovskite film P that has been formed is good, it is necessary to ascertain the distribution of the crystalline state over not just a portion but the entire perovskite film P in the crystalline state confirmation step, as described above.

In addition, as described above, the power generation efficiency of a perovskite solar cell is known to be correlated with the band gap Eg. Here, as one example, let us assume that in a perovskite solar cell of a certain structure has high power generation efficiency when the band gap Eg is about 1.4 to 1.5 eV. In this case, according to equation (1), the wavelength λ of light when Eg is 1.4 eV is approximately 890 nm, and the wavelength λ of light when Eg is 1.5 eV is approximately 840 nm, so, from this result, if the measurement result of the absorption edge at each of the measurement positions 37 of the perovskite film P is approximately 840 nm to 890 nm, the perovskite solar cell will have an ideal power generation efficiency.

In this manner, in the crystalline state confirmation step of the present embodiment for calculating the absorption edge wavelength of the absorption spectrum at each position of the perovskite film P, it is possible not only to confirm whether the crystalline state is essentially uniform over the entire perovskite film P, but also to calculate the parameter (band gap Eg) that is directly linked to the power generation efficiency of the perovskite solar cell.

On the other hand, the density of crystals can also be an evaluation index for the crystalline state of the perovskite film P. When manufacturing a perovskite solar cell, the crystalline state of the perovskite film P is preferably dense; if gaps between the crystals are large and the crystalline state is sparse, the power generation efficiency will be lower compared to when dense, making the perovskite film P not suitable for forming a solar cell.

In this manner, if the crystalline state of the perovskite film P is sparse, when the absorption spectrum is acquired with the crystalline state confirmation unit 3 described above, the light absorbance is measured to be low overall, as shown by the curve indicated by the broken line in FIG. 2. In particular, in the short-wavelength region (for example, λ=400 nm to 500 nm (violet to blue light)) in which the light absorbance is flat, differences in light absorbance due to the density of the crystals can be clearly seen. Accordingly, the light absorbance in this short-wavelength region can be acquired as the numerical data for each of the measurement positions 37 in the crystalline state confirmation step, and whether the light absorbance in this short-wavelength region is relatively high over the entire perovskite film P can be evaluated, to thereby confirm the crystalline state of the perovskite film P. Of course, the light absorbance in the short-wavelength region may be acquired together with the wavelength of the absorption edge described above as the numerical data for each of the measurement positions 37.

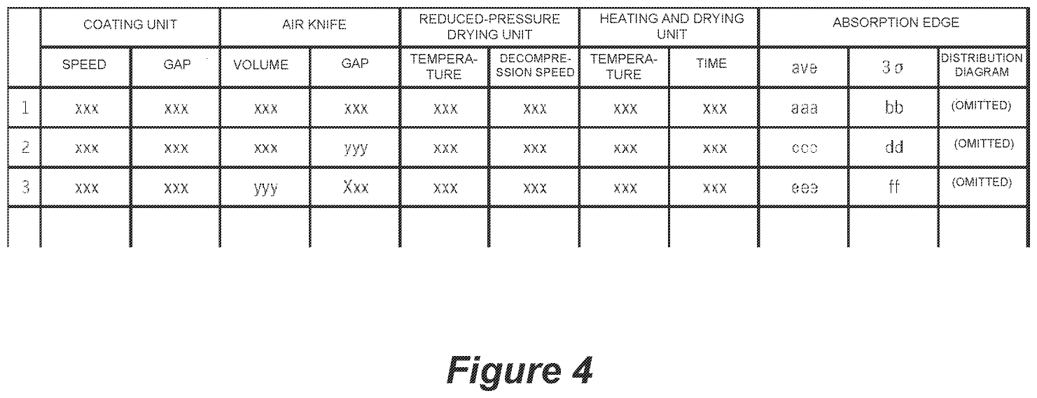

In addition, in the present embodiment, the numerical data distribution obtained in the crystalline state confirmation step is linked with each parameter (that is, operating conditions) used in the associated film-forming step and stored in the storage device 35 as one piece of film formation data, which, together with previously-stored film formation data, forms a data group as shown in FIG. 4. Specifically, the information in one row of the matrix shown in FIG. 4 is one piece of film formation data, and a data group spanning a plurality of rows is formed with the accumulation of a plurality of pieces of these film formation data. The “distribution diagram” portion, which is omitted in FIG. 4, stores two-dimensional color-coded maps created on the basis of the numerical data distribution obtained in the crystalline state confirmation step.

As described above, after the perovskite film P is formed on the substrate W by carrying out the film-forming step and the crystalline state confirmation step using the perovskite film forming device 1, and the crystalline state of the perovskite film P is confirmed on the basis of the numerical data distribution, an operator or an AI feeds back this numerical data distribution information to adjust the film formation conditions used when forming said perovskite film P, and the adjusted conditions are used as the film formation conditions for the subsequent substrates W.

Specifically, whether each piece of numerical data constituting the numerical data distribution is within a prescribed numerical range, or, if there are numerical data outside of the prescribed numerical range, to which portion of the perovskite film P these numerical data belong, are checked. Then, if there is an abnormal location in the confirmation result, at least some of the coating conditions in the coating unit 10 and the drying conditions in the air knife 21, the reduced-pressure drying unit 22, and the heating and drying unit 23 forming the drying unit 20, are changed to adjust the film formation conditions for the subsequent substrates W so that the numerical data distribution obtained in the subsequent substrates W falls within a prescribed numerical range (in the present embodiment, λ=approximately 840 to 890 nm) over the entire perovskite film P.

The step of adjusting the operating conditions of the film-forming step is referred to as the condition adjustment step in this description, and, by carrying out this condition adjustment step, the crystalline state of the perovskite film P on the subsequent substrates W can be improved overall.

In particular, when forming the perovskite film P having an unstable crystal formation process, even if perovskite film P is formed on two substrates W under the same coating and drying conditions, there is the possibility that differences occur in the crystalline states due to changes in the temperature or humidity around the film-forming unit 2, for example. Therefore, the crystalline state confirmation unit 3 and the crystalline state confirmation step carried out thereby are preferably incorporated inline. That is, it is preferable that confirmation of the crystalline state by the crystalline state confirmation unit 3 is carried out each time the perovskite film P is formed by the film-forming unit 2, and that the results thereof are immediately fed back, through the condition adjustment step, to the conditions for the subsequent film-forming processes.

Here, as described above, in the present embodiment, the numerical data distribution obtained in the crystalline state confirmation step is stored in the storage device 35 as film formation data together with the operating conditions of the film-forming step, forming a data group as shown in FIG. 4. If a data group is formed in this manner, it becomes possible to ascertain trends in relative changes in the crystalline state of the perovskite film P with respect to changes in the parameters, such as how the crystalline state of which relative portion of the perovskite film P changes depending on which parameter is changed in what way, by comparing the film formation data in the data group.

Then, an operator or an AI that is aware of the trend can use the information of this data group when feeding back, in the condition adjustment step, the numerical data distribution obtained in the crystalline state confirmation step, to adjust the operating conditions of the film-forming step for the subsequent substrates W.

Specifically, for example, in the condition adjustment step, the operator or the AI first extracts, from the data group, film formation data (hereinafter referred to as film formation data D1) having a numerical data distribution similar to the numerical data distribution obtained in the crystalline state confirmation step.

Next, the operator or the AI extracts film formation data D2, which are film formation data similar to the film formation data D1 but that have a better numerical data distribution than the film formation data D1, and compares the operating conditions of the film-forming step between those of the film formation data D1 and the film formation data D2.

Then, from the result thereof, the operator or the AI determines which parameter should be changed and by how much with respect to the operating conditions of the current film-forming step, which is reflected on the operating conditions of the film-forming steps for the subsequent substrates W. As a result, it becomes possible to efficiently improve the crystalline state of the perovskite film P formed on the subsequent substrates W.

It should be noted that this condition adjustment step is not limited to being carried out each time the crystalline state confirmation step is carried out, and may be carried out, for example, only when the standard deviation of the numerical data distribution obtained in the crystalline state confirmation step exceeds a prescribed threshold value.

### Embodiment 2

The crystalline state confirmation unit in the perovskite film forming device according to another embodiment of the present disclosure will be described next with reference to FIG. 5.

In the crystalline state confirmation unit 3 of the present embodiment described in Embodiment 1 above, as shown in FIG. 3, one measuring means (combination of the light source 31 (not shown) and the spectral detector 32) carries out scanning, and the one measuring means confirms the crystalline state of the perovskite film P at a plurality of measurement positions. In contrast, in the crystalline state confirmation unit 3 of the present embodiment, a plurality of measuring means are provided, and the measuring means are respectively connected to a common storage device 35. The crystalline state is confirmed at a plurality of measurement positions using these plurality of measuring means.

By providing a plurality of measuring means in this manner, it is possible to simultaneously carry out the crystalline state confirmation step at a plurality measurement positions without moving the measuring means.

When observing the perovskite film P in a state in which heating and drying has completed and crystal growth has stopped, there is no problem if a time lag occurs in the confirmation of the crystalline state at each measurement position. On the other hand, when confirming the crystalline state in a state in which the crystalline state is constantly changing, it is preferable to confirm the crystalline state simultaneously at each measurement position using a plurality of measuring means in this manner, because it allows verification using uniform time parameters at each measurement position.

In addition, in Embodiment 1, the light 34 that has been transmitted through the substrate W and the perovskite film P enters the spectral detector 32, but both the light source 31 and the spectral detector 32 may be arranged above the perovskite film P, and light 24 that is reflected by the perovskite film P may be made to enter the spectral detector 32, as in the present embodiment.

### Embodiment 3

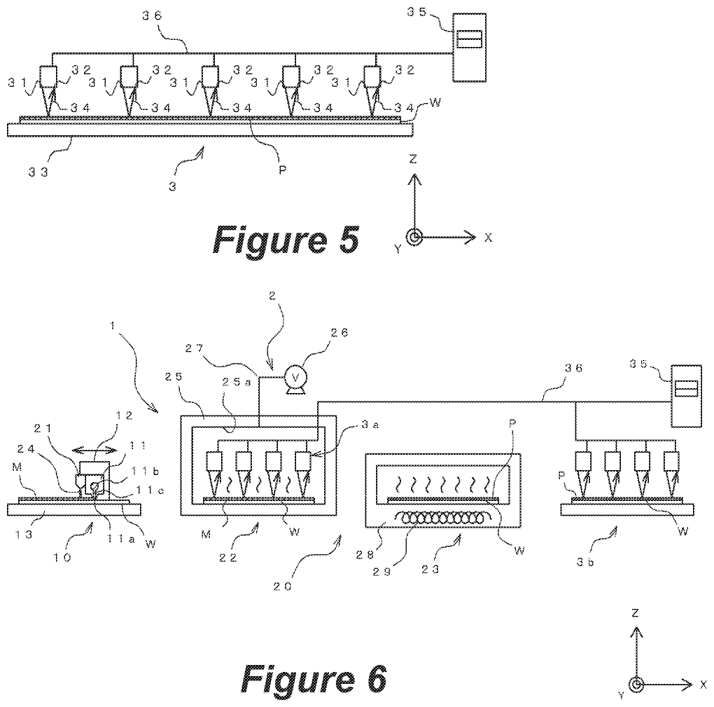

A perovskite film forming device according to yet another embodiment of the present disclosure will be described next with reference to FIG. 6.

The drying unit 20 in the crystalline state confirmation unit 3 of the present embodiment is further provided with a crystalline state confirmation unit 3a inside the reduced-pressure drying unit 22, which is the first drying unit. The crystalline state confirmation unit 3a has a plurality of measuring means, in the same manner as in Embodiment 2, and carries out crystalline state confirmation at a plurality of measurement positions essentially simultaneously using the plurality of measuring means. The measurement target at this time is the coating film M containing perovskite prior to becoming the perovskite film P.

The inventors have confirmed that a small difference in the reduced-pressure drying time on the order of 10 seconds in the reduced-pressure drying step causes a large difference in the color of the coating film M. It can be predicted from the foregoing that the crystalline state (density of the crystal nuclei) of the perovskite in the coating film M changes greatly in a short period of time in the reduced-pressure drying step, so it is conceivable that, compared to the conditions of heating and drying (second drying step), the conditions of reduced-pressure drying greatly affect the ultimate density and size of crystals in the perovskite film P.

Therefore, by carrying out the crystalline state confirmation step before the second drying step in the perovskite film forming device 1 of the present embodiment, it is possible to remove the second drying conditions and evaluate the relationship between the crystalline state of the perovskite film P and the reduced-pressure drying conditions (first drying conditions) which are thought to greatly affect the size and density of the crystals in the perovskite film P.

In addition, since the crystalline state in the coating film M changes constantly during the reduced-pressure drying step, by carrying out confirmation of the crystalline state at a plurality of measurement positions essentially simultaneously using a plurality of measuring means as in the present embodiment, it becomes possible to keep the timing consistent at which the crystalline state is confirmed for each measurement position, and to accurately evaluate the effects of the reduced-pressure drying conditions on the crystalline state of the perovskite film P.

Here, by carrying out the crystalline state confirmation step at a prescribed timing, such as confirming the crystalline state after a prescribed period of time has elapsed after starting reduced-pressure drying, the time parameters at each measurement point can be made uniform to make it possible to accurately verify the effect that the reduced-pressure drying parameters excluding the drying time have on the crystalline state of the coating film M. At this time, in the embodiment shown in FIG. 6, the crystalline state confirmation unit 3a is provided inside the reduced-pressure drying unit 22, but the invention is not limited thereto; for example, the crystalline state confirmation unit 3a may be provided outside of the reduced-pressure drying unit 22, and the crystalline state confirmation step may be carried out after the first drying step and before the second drying step.

On the other hand, the crystalline state of the coating film M can be checked intermittently during the reduced-pressure drying step by the crystalline state confirmation unit 3a in the reduced-pressure drying unit 22, and the result thereof can be fed back in real time. It is thereby possible to detect the timing at which the coating film M reaches a prescribed crystalline state (crystal nuclei density) on each substrate, and to end the reduced-pressure drying when the coating film M reaches a given crystalline state.

In addition to the crystalline state confirmation unit 3a inside the reduced-pressure drying unit 22, a crystalline state confirmation unit 3b may be provided to confirm the crystalline state of the perovskite film P after completion of the heating and drying carried out by the heating and drying unit 23. It is thereby possible to separately verify the effects of the heating and drying conditions and the effects of the reduced-pressure drying conditions on the crystalline state of the perovskite film P. In particular, when the perovskite film forming device is incorporated into a mass production line, a plurality of the heating and drying units 23 may be arranged in parallel to maintain tact time, and in such cases, non-uniform temperature distribution can be expected in the heating and drying units 23. Therefore, it is preferable to provide the crystalline state confirmation unit 3a that confirms the crystalline state of the coating film M before the heating and drying step, and the crystalline state confirmation unit 3b that confirms the crystalline state of the perovskite film P after the heating and drying step.

By using the perovskite film forming method and the perovskite film forming device described above, it is possible to obtain a perovskite solar cell that has stable power generation efficiency.

Here, the perovskite film forming method and the perovskite film forming device of the present invention are not limited to the embodiments described above, and may take other forms within the scope of the present invention. For example, in the description above, in the crystalline state confirmation step, the absorption spectrum of light irradiated on the perovskite film is acquired, and the wavelength at the long-wavelength side edge of the absorption spectrum is acquired as the numerical data, but the invention is not limited thereto. For example, the surface roughness of the perovskite film may be acquired as the numerical data, and it may be confirmed whether said numerical data are within a prescribed numerical range. In this manner, it is possible to ascertain the crystalline state by estimating the size of the crystals of the perovskite film at each measurement position, and to carry out the condition adjustment step on the basis thereof.

In addition, it is possible to use a photoluminescence method, that is, a method in which laser light is made incident on the perovskite film P to excite the electrons in the perovskite film P, and emission light emitted from the perovskite film P when these electrons return to the ground state is acquired. Then, the peak wavelength of the emission light can be acquired as the numerical data, and it may be confirmed whether said numerical data are within a prescribed numerical range. In this manner, it is possible to easily ascertain the power generation efficiency of the perovskite film P for each measurement position, in the same manner as when acquiring the absorption spectrum, and to carry out the condition adjustment step on the basis thereof.

In addition, in the condition adjustment step in the description above, the operating conditions for the perovskite film P formation are adjusted so that the numerical data obtained in the subsequent crystalline state confirmation steps would become essentially uniform over the entire perovskite film P, but this is not necessarily essential. For example, the conditions for the perovskite film P formation may be intentionally adjusted so that the crystalline state of the outer peripheral portion of the perovskite film P is different from that of all the other portions.

In addition, the outlet of the air knife 21 may be separated into small sections in the Y-axis direction so that the volume and temperature of the dry air 24 can be individually adjusted, or the area of the stage 28 of the heating and drying unit 23 on which the substrate W is placed may be divided into small sections so that the heating temperature can be adjusted individually for each area, thereby making the drying conditions different for each small area of the perovskite film P.

In addition, in the description above, the crystalline state confirmation step and the condition adjustment step are carried out each time the film-forming step is carried out, but the invention is not limited thereto; for example, the crystalline state confirmation step and the condition adjustment step may be carried out once every several film-forming steps.

In addition, in the condition adjustment step, instead of carrying out feedback of the operating conditions for subsequent film-forming steps based only on the numerical data distribution for the perovskite film P that has been subjected to the crystalline state confirmation step, numerical data distributions for a plurality of the most recent perovskite films P formed under the same film formation conditions may be referenced, and the trend in the changes in these numerical data distributions may be used as a basis of judgment to carry out feedback of the operating conditions for the subsequent film-forming steps.

In addition, in the description above, film formation data are accumulated to form a data group, but this is not necessarily essential.

Additionally, in the description above, the film-forming unit 2 is composed of the coating unit 10 and the drying unit 20, and the perovskite film P is formed by the coating step and the drying step, but the invention is not limited thereto; for example, the film-forming unit 2 may be a sputtering device and the film may be formed by means of sputtering.

In addition, in the description above, the drying unit 20 has the air knife 21, the reduced-pressure drying unit 22, and the heating and drying unit 23, but a crystal nuclei formation unit (first drying unit) that carries out the crystal nuclei formation step of another method may be used instead of the reduced-pressure drying unit 22. For example, a gas quenching method in which air or gas is blown on the coating film M, similar to the air knife, or a method in which a poor solvent is applied to expel the solvent in the coating film M, may be employed.

1. A perovskite film forming method, comprising:
forming a perovskite film on a substrate;
confirming a crystalline state of the perovskite film on the substrate by means of measurement; and
adjusting operating condition in the forming of the perovskite film for a subsequent substrate on the basis of measurement result obtained in the confirming of the crystalline state,
in the confirming of the crystalline state, a plurality of measurement positions being provided over the entire perovskite film on the substrate and numerical data being acquired for each measurement position to acquire a numerical data distribution of the crystalline state for the entire perovskite film.

2. The perovskite film forming method according to claim 1, wherein
in the adjusting of the operating condition, the operating condition in the forming of the perovskite film is adjusted so that the numerical data distribution acquired in the confirming of the crystalline state for the subsequent substrate falls within a prescribed numerical range over the entire perovskite film.

3. The perovskite film forming method according to claim 1, wherein
the numerical data distributions acquired in the confirming of the crystalline state in the past are accumulated together with information on the operating conditions in the forming of the perovskite film to form a data group, and
in the adjusting of the operating condition, the operating condition in the forming of the perovskite film for the subsequent substrate is adjusted by further using information of the data group.

4. The perovskite film forming method according to claim 1, wherein
in the confirming of the crystalline state, an absorption spectrum of light irradiated on the perovskite film is acquired, and a wavelength at a long-wavelength side edge of the absorption spectrum is acquired as the numerical data.

5. The perovskite film forming method according to claim 1, wherein
in the confirming of the crystalline state, an absorption spectrum of light irradiated on the perovskite film is acquired, and light absorbance at a short-wavelength region of the absorption spectrum is acquired as the numerical data.

6. The perovskite film forming method according to claim 1, wherein
in the confirming of the crystalline state, surface roughness of the perovskite film is acquired as the numerical data.

7. The perovskite film forming method according to claim 1, wherein
in the confirming of the crystalline state, a photoluminescence method is implemented to acquire, as the numerical data, a peak wavelength of light emitted from the perovskite film.

8. The perovskite film forming method according to claim 1, wherein
the forming of the perovskite film includes forming a coating film containing perovskite on the substrate by coating, and drying the coating film formed on the substrate to form the perovskite film, and
in the adjusting of the operating condition, forming condition of the coating film in the forming of the coating film and/or drying condition of the coating film in the drying of the coating film is adjusted.

9. The perovskite film forming method according to claim 1, wherein
the confirming of the crystalline state and the adjusting of the operating condition are carried out each time the forming of the perovskite film is carried out.

10. A perovskite film forming method, comprising:
forming a perovskite film, the forming of the perovskite film including forming a coating film containing perovskite on a substrate by coating, and a drying step for drying the coating film formed on the substrate to form the perovskite film;
confirming a crystalline state of the coating film on the substrate by means of measurement; and
adjusting operating condition in the forming of the perovskite film on the basis of measurement result obtained in the confirming of the crystalline state,
in the confirming of the crystalline state, a plurality of measurement positions being provided over the entire coating film on the substrate and numerical data being acquired for each measurement position to acquire a numerical data distribution of the crystalline state for the entire coating film,
the drying of the coating film including a first drying to increase crystal nuclei of perovskite and a second drying to grow perovskite crystals around the crystal nuclei after the first drying, and
the confirming of the crystalline state being carried out during the first drying or after the first drying and before the second drying.

11. The perovskite film forming method according to claim 10, wherein
the first drying includes a reduced-pressure drying in which the coating film is maintained under a reduced-pressure environment.

12. The perovskite film forming method according to claim 10, wherein
the confirming of the crystalline state is carried out after a prescribed period of time has elapsed after the start of the first drying.

13. The perovskite film forming method according to claim 10, wherein
in the confirming of the crystalline state, measurements are carried out at a plurality of the measurement positions essentially simultaneously.

14. A perovskite film forming device, comprising:
a film-forming unit configured to form a perovskite film on a substrate; and
a crystalline state confirmation unit configured to confirm a crystalline state of the perovskite film on the substrate by means of measurement,
in the crystalline state confirmation unit, a plurality of measurement positions being provided over the entire perovskite film on the substrate and numerical data being acquired for each measurement position to acquire a numerical data distribution of the crystalline state for the entire perovskite film.

15. A perovskite film forming device, comprising:
a film-forming unit including a coating unit configured to form a coating film containing perovskite on a substrate by coating, and a drying unit configured to dry the coating film formed on the substrate to form a perovskite film; and
a crystalline state confirmation unit configured to confirm a crystalline state of the coating film on the substrate by means of measurement,
in the crystalline state confirmation unit, a plurality of measurement positions being provided over the entire coating film on the substrate and numerical data being acquired for each measurement position to acquire a numerical data distribution of the crystalline state for the entire coating film,
the drying unit including a first drying unit configured to carry out a first drying to increase crystal nuclei of perovskite and a second drying unit configured to carry out a second drying to grow perovskite crystals around the crystal nuclei after the first drying carried out by the first drying unit, and
the crystalline state confirmation unit being configured to confirm the crystalline state of the coating film during the first drying carried out by the first drying unit or after the first drying and before the second drying carried out by the second drying unit.

16. The perovskite film forming device according to claim 15, wherein
the first drying unit includes a reduced-pressure drying unit that is configured to maintain the coating film under a reduced-pressure environment.

17. The perovskite film forming device according to claim 15, wherein
the crystalline state confirmation unit has a plurality of detectors and each of the detectors is configured to carry out measurements at each of the measurement positions.
